(19) United States
(12) Patent Application Publication
(10) Pub. No.: US 2025/0338618 A1
(43) Pub. Date: Oct. 30, 2025

(54) DISPLAY DEVICE AND ELECTRONIC DEVICE INCLUDING THE SAME

(71) Applicant: Samsung Display Co., LTD., Yongin-si (KR)

(72) Inventors: SUNKWUN SON, Yongin-si (KR); CHEOL-GON LEE, Yongin-si (KR)

(21) Appl. No.: 19/008,898

(22) Filed: Jan. 3, 2025

(30) Foreign Application Priority Data
Apr. 29, 2024 (KR) 10-2024-0057150

(51) Int. Cl. H10D 86/40; H10D 86/60

(52) U.S. Cl. CPC H10D 86/441; H10D 86/481; H10D 86/60

(57) ABSTRACT

A display device includes a substrate, a first active pattern disposed on the substrate, and extending in a first direction, a first conductive pattern disposed on the first active pattern, and overlapping a portion of the first active pattern in a plan view, a second conductive pattern disposed on the first conductive pattern, and extending in a second direction which intersects with the first direction, and a second active pattern disposed on the second conductive layer, and defining a storage capacitor with the first conductive pattern and the second conductive pattern.

This application claims priority to Korean Patent Application No. 10-2024-0057150, filed on Apr. 29, 2024, and all the benefits accruing therefrom under 35 U.S.C. § 119, the content of which in its entirety is herein incorporated by reference.

### BACKGROUND

### 1. Field

Embodiments relate to a display device. More particularly, embodiments relate to the display device which provides visual information.

### 2. Description of the Related Art

A display device is a device that displays an image to provide visual information to a user. Types of display device include a liquid crystal display and an organic light-emitting diode display and the like. The display device may be operated by thin film transistors, capacitors, and multiple lines which have complex interconnections.

Recently, as a demand for compact and high-resolution display device increases, a demand for efficient space arrangement, connection structure, driving method, and improvement of quality of images implemented among thin film transistors, capacitors, and lines included in the display device is increasing.

### SUMMARY

Embodiments provide a display device with improved display quality.

A display device according to an embodiment includes a substrate, a first active pattern disposed on the substrate, and extending in a first direction, a first conductive pattern disposed on the first active pattern, and overlapping a portion of the first active pattern in a plan view, a second conductive pattern disposed on the first conductive pattern, and extending in a second direction which intersects with the first direction, and a second active pattern disposed on the second conductive layer, and defining a storage capacitor with the first conductive pattern and the second conductive pattern.

In an embodiment, the storage capacitor may include a first storage capacitor defined by overlapping portions of the first conductive pattern and the second conductive pattern and a second storage capacitor defined by overlapping portions of the second conductive pattern and the second active pattern.

In an embodiment, the display device may further include a gate voltage line disposed on the second active pattern, extending in the second direction, and to which a gate voltage is configured to be applied, a horizontal power voltage line disposed on the gate voltage line, and extending in the second direction, a third conductive pattern disposed on the gate voltage line, and spaced apart from the horizontal power voltage line in the first direction, and a fourth conductive pattern disposed on the gate voltage line, and spaced apart from the third conductive pattern and the horizontal power voltage line.

In an embodiment, the second conductive pattern may be electrically connected to the first active pattern, and the third conductive pattern may be spaced apart from the second conductive pattern in the first direction in a plan view, and is electrically connected to the first active pattern.

In an embodiment, the first active pattern, the first conductive pattern, the second conductive pattern, and the third conductive pattern may define a driving transistor together.

In an embodiment, the second conductive pattern may be a source electrode of the driving transistor, the third conductive pattern may be a drain electrode of the driving transistor, and a portion of the first conductive pattern overlapping the first active pattern in the plan view may be a gate electrode of the driving transistor.

In an embodiment, the first conductive pattern may be electrically the second active pattern, and the fourth conductive pattern may be spaced apart from the first conductive pattern in the first direction in a plan view, and may be electrically connected to the second active pattern.

In an embodiment, the second active pattern, the gate voltage line, the first conductive pattern, and the fourth conductive pattern may define a switching transistor together.

In an embodiment, the first conductive pattern may be a drain electrode of the switching transistor, the fourth conductive pattern may be a source electrode of the switching transistor, and a portion of the gate voltage line overlapping the second active pattern in the plan view may be a gate electrode of the switching transistor.

In an embodiment, a power voltage may be configured to be applied to the horizontal power voltage line, and the horizontal power voltage line may be electrically connected to the second conductive pattern.

In an embodiment, the second conductive pattern and the first active pattern may be connected through a first contact hole, the second active pattern and the first conductive pattern may be connected through a second contact hole, the horizontal power voltage line and the second conductive pattern may be connected through a third contact hole, the third conductive pattern and the first active pattern may be connected through a fourth contact hole, and the fourth conductive pattern and the second active pattern may be connected through a fifth contact hole.

In an embodiment, the first contact hole, the third contact hole, and the fourth contact hole may be arranged along a first imaginary vertical line parallel to the first direction, in a plan view, and the second contact hole and the fifth contact hole may be arranged along a second imaginary vertical line parallel to the first direction and spaced apart from the first imaginary vertical line, in a plan view.

In an embodiment, the display device may further include a data voltage line disposed on the horizontal power voltage line, and extending in the first direction and a fifth conductive pattern disposed on the data voltage line, and spaced apart from the horizontal power voltage line in the first direction, in a plan view.

In an embodiment, the data voltage line may be connected to the fourth conductive pattern through a sixth contact hole, and the sixth contact hole may overlap the fifth contact hole in a plan view.

In an embodiment, the fifth conductive pattern may be electrically connected to the third conductive pattern through a seventh contact hole, and the seventh contact hole may overlap the fourth contact hole in a plan view.

In an embodiment, the fifth conductive pattern and the data voltage line may adjoin each other in a plan view.

In an embodiment, the display device may further include a vertical power voltage line disposed between the horizontal power voltage line and the data voltage line, and extending in the first direction.

In an embodiment, the second active pattern may overlap a portion of the first active pattern in a plan view.

A display device according to an embodiment includes a substrate, a first active pattern disposed on the substrate, and extending in the first direction, a first conductive pattern disposed on the first active pattern, and overlapping a portion of the first active pattern in a plan view, a second conductive pattern disposed on the first conductive pattern, extending in a second direction which intersects with the first direction, and contacting a portion of the first active pattern through a first contact hole, a second active pattern disposed on the second conductive pattern, overlapping a portion of each of the first conductive pattern and the second conductive pattern in the plan view, and contacting a portion of the first conductive pattern through a second contact hole, a gate voltage line disposed on the second active pattern, extending in the second direction, and to which a gate voltage is configured to be applied, a horizontal power voltage line disposed on the gate voltage line, to which a power voltage is configured to be applied, and contacting a portion of the second conductive pattern through a third contact hole, a third conductive pattern disposed in the same layer as the horizontal power voltage line, and contacting a portion of the first active pattern through a fourth contact hole, and a fourth conductive pattern disposed in the same layer as the horizontal power voltage line, and contacting a portion of the second active pattern through a fifth contact hole.

In an embodiment, the first contact hole, the third contact hole, and the fourth contact hole may be arranged along a first imaginary vertical line parallel to the first direction in a plan view, and the second contact hole and the fifth contact hole may be arranged along a second imaginary vertical line parallel to the first direction and spaced apart from the first imaginary vertical line.

In a display device according to embodiments of the present disclosure, a first active pattern disposed on a substrate and extending in a first direction, a first conductive pattern overlapping a portion of the first active pattern in a plan view, a second conductive pattern disposed on the first conductive pattern and extending in a second direction which intersects the first direction, and a second active pattern defining a storage capacitor together with the first conductive pattern and the second conductive pattern. In addition, since the display device may include a sensing circuit for external compensation, a pixel included in the display device may include two transistors. Accordingly, the number of pixels included in the display device may increase, therefore the display device may be implemented with a high resolution.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to an embodiment of the present disclosure.

FIG. 2 is a circuit diagram illustrating a pixel included in the display device of FIG. 1.

FIGS. 3, 4, 5, 6, 7, 8, 9, 10, 11, 12, 13, 14, and 15 are plan views illustrating an example of the pixel included in the display device of FIG. 1.

FIG. 16 is a cross-sectional view illustrating a cross-section of the pixel of the display device of FIG. 1 taken along line I-I′ of FIG. 15.

FIG. 17 is a cross-sectional view illustrating a cross-section of the pixel of the display device of FIG. 1 taken along line II-II′ of FIG. 15.

FIGS. 18 and 19 are plan views illustrating another example of the pixel included in the display device of FIG. 1.

FIGS. 20, 21, 22, 23, and 24 are plan views illustrating still another example of the pixel included in the display device of FIG. 1.

FIG. 25 is a view illustrating an electronic device implemented by the display device of FIG. 1.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element, it can be directly on the other element or intervening elements may be present therebetween. In contrast, when an element is referred to as being “directly on” another element, there are no intervening elements present.

Hereinafter, display devices in accordance with embodiments will be described in more detail with reference to the accompanying drawings. The same reference numerals are used for the same components in the drawings, and redundant descriptions of the same components will be omitted.

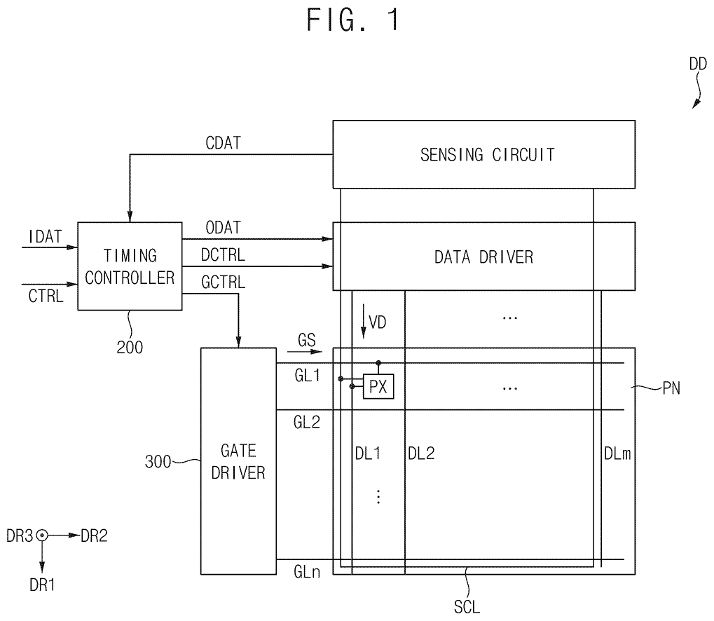

FIG. 1 is a block diagram illustrating a display device according to an embodiment of the present disclosure.

Referring to FIG. 1, the display device DD may include a display panel PN, a timing controller CON, a gate driver GDV, a data driver DDV, and a sensing circuit SSC.

The display panel PN may include a display area defined as an area displaying an image and a peripheral area adjacent to the display area. A plurality of the pixels PX, a plurality of the gate lines GL1, GL2, . . . , GLn, a plurality of the data lines DL1, DL2, . . . , DLm, and a sensing connecting line SCL may be disposed in the display area. The gate driver GDV, the data driver DDV, and the sensing circuit SSC may be disposed in the peripheral area.

In this specification, a plane may be defined by a first direction DR1 and a second direction DR2 which intersects with the first direction DR1. For example, the second direction DR2 may be perpendicular to the first direction DR1. In addition, a third direction may be perpendicular to the plane.

The plurality of pixels PX may be arranged in a matrix form including a plurality of matrix rows and a plurality of matrix column. For example, the plurality of pixels PX may be arranged along the first direction DR1 and the second direction DR2. Each of the plurality of pixels PX may be electrically connected to a gate line among the plurality of the gate lines GL1, GL2, . . . , GLn, a data line among the plurality of the data lines DL1, DL2, . . . , DLm, and the sensing connecting line SCL.

Each of the plurality of the gate lines GL1, GL2, . . . , GLn may extend in the second direction DR2. In addition, the plurality of the gate lines GL1, GL2, . . . , GLn may be arranged along the first direction DR1. Each of the plurality of the data lines DL1, DL2, . . . , DLm may extend in the first direction DR1. In addition, the plurality of the data lines DL1, DL2, . . . , DLm may be arranged along the second direction DR2.

The timing controller CON may receive an input image data IDAT and an input control signal CTRL from a host processor (e.g. a graphic processing unit, GPU, and the like). In an embodiment, the input image data IDAT may include a red image data, a green image data, and a blue image data. In an embodiment, the input image data IDAT may further include a white image data. In another embodiment, the input image data IDAT may include a magenta image data, a yellow image data, and a cyan image data. The input control signal CTRL may include a master clock signal and a data enable signal. The input control signal CTRL may further include a vertical synchronization signal and a horizontal synchronization signal.

The timing controller CON may generate a gate control signal GCTRL, a data control signal DCTRL, and an output image data ODAT based on an input image data IDAT and an input control signal CTRL.

The timing controller CON may generate the gate control signal GCTRL for controlling an operation of the gate driver GDV based on the input control signal CTRL and output the gate control signal GCTRL to the gate driver GDV. The gate control signal GCTRL may include a vertical start signal and a gate clock signal.

The timing controller CON may generate the data control signal DCTRL for controlling an operation of the data driver DDV based on the input control signal CTRL and output the data control signal DCTRL to the data driver DDV. The data control signal DCTRL may include a horizontal start signal and a load signal.

The timing controller CON may receive the input image data IDAT and the input control signal CTRL and generate the output image data ODAT. The timing controller CON may output the output image data ODAT to the data driver DDV.

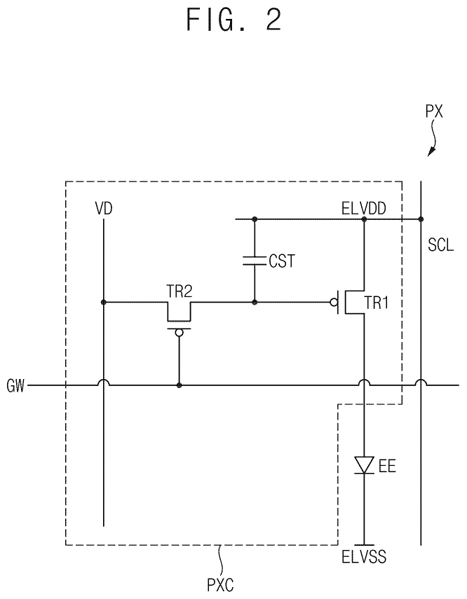

The gate driver GDV may generate a gate signal GS for driving the plurality of gate lines GL1, GL2, . . . , GLn in response to the gate control signal GCTRL input from the timing controller CON. For example, the gate signal GS may include a gate write signal (e.g., a gate write signal GW of FIG. 2). The gate driver GDV may output the gate signal GS to each of the plurality of gate lines GL1, GL2, . . . , GLn. For example, the gate driver GDV may sequentially output the gate signals to the plurality of gate lines GL1, GL2, . . . , GLn.

The data driver DDV may receive the data control signal DCTRL and the output image data ODAT from the timing controller CON. The data driver DDV may generate a data voltage VD that converts the output image data ODAT into an analog voltage. The data driver DDV may output the data voltage VD to the plurality of data lines DL1, DL2, . . . , DLm. In an embodiment, the data driver DDV may be mounted on the display panel PN or integrated in the periphery of the display panel PN. In another embodiment, the data driver DDV may be implemented as one or more an integrated circuits (“IC”).

The sensing circuit SSC may be electrically connected to the sensing connecting line SCL. In addition, the sensing connecting line SCL may be connected to power voltage lines that apply a power voltage to a plurality of pixels PX. Accordingly, the sensing circuit SSC may sample a sensing current corresponding to a first power voltage (e.g., a first power voltage ELVDD of FIG. 2) from the sensing connecting line SCL when the display device DD is driven in the sensing mode, and may calculate a threshold voltage value for measuring deterioration of a transistor disposed in the display area using the sensing current. The sensing circuit SSC may provide a compensation data CDAT including the calculated threshold voltage value to the timing controller CON. In other words, the sensing circuit SSC may be an external compensation circuit for applying a compensation voltage to each of the plurality of pixels PX and preventing deterioration of the transistor.

FIG. 2 is a circuit diagram illustrating a pixel included in the display device of FIG. 1.

Referring to FIG. 2, a pixel PX may include a pixel circuit PXC and a light-emitting element EE. The pixel circuit PXC may include a first transistor TR1, a second transistor TR2, and a storage capacitor CST. The pixel circuit PXC may provide a driving current to the light-emitting element EE, and the light-emitting element EE may generate light based on the driving current.

A first terminal of the first transistor TR1 may be connected to a first power voltage line. For example, the first transistor TR1 may receive the first power voltage ELVDD from the first power voltage line through the first terminal, and may generate a driving current corresponding to the first power voltage ELVDD.

A second terminal of the first transistor TR1 may be connected to the light-emitting element EE. For example, the first transistor TR1 may provide the driving current to the light-emitting element EE through the second terminal. A gate terminal of the first transistor TR1 may be connected to the first terminal of the storage capacitor CST. In this specification, the first transistor TR1 may be referred to as a “driving transistor”.

In an embodiment, the first transistor TR1 may be a p-channel metal oxide semiconductor (“PMOS”) transistor. In another embodiment, the first transistor TR1 may be an n-channel metal oxide semiconductor (“NMOS”) transistor.

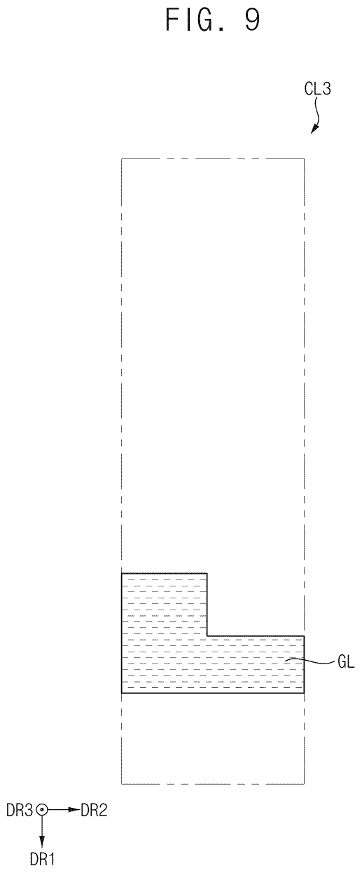

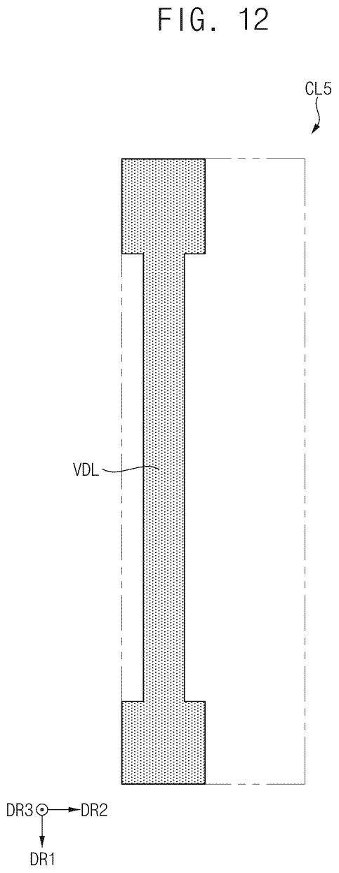

A first terminal of the second transistor TR2 may be connected to a data voltage line (e.g., a data voltage line VDL of FIG. 12). The data voltage VD may be applied to the data voltage line. A second terminal of the second transistor TR2 may be connected to the gate terminal of the first transistor TR1. In addition, the second terminal of the second transistor TR2 may be connected to the first terminal of the storage capacitor CST. A gate terminal of the second transistor TR2 may be connected to a gate voltage line (e.g., the gate voltage line GL of FIG. 9).

The second transistor TR2 may be turned on by the gate write signal GW provided by the gate voltage line. When the second transistor TR2 is turned on, the second transistor TR2 may provide the data voltage VD to the first transistor TR1. In this specification, the second transistor TR2 may be referred to as a switching transistor.

In an embodiment, the second transistor TR2 may be a PMOS transistor. In another embodiment, the second transistor TR2 may be an NMOS transistor.

The first terminal of the storage capacitor CST may be connected to each of the gate terminal of the first transistor TR1 and the second terminal of the second transistor TR2. In addition, the second terminal of the storage capacitor CST may be connected to the first power voltage line. The storage capacitor CST may maintain the voltage level of the gate terminal of the first transistor TR1 during the inactive period of the gate write signal GW provided by the gate voltage line.

The driving current may be applied to one end of the light-emitting element EE, and a second power voltage ELVSS may be applied to another end of the light-emitting element EE.

Referring further to FIG. 1, the sensing connecting line SCL may be connected to the first power voltage line. The threshold voltage of the first transistor TR1 may be compensated through the sensing connecting line SCL connected to the sensing circuit SSC.

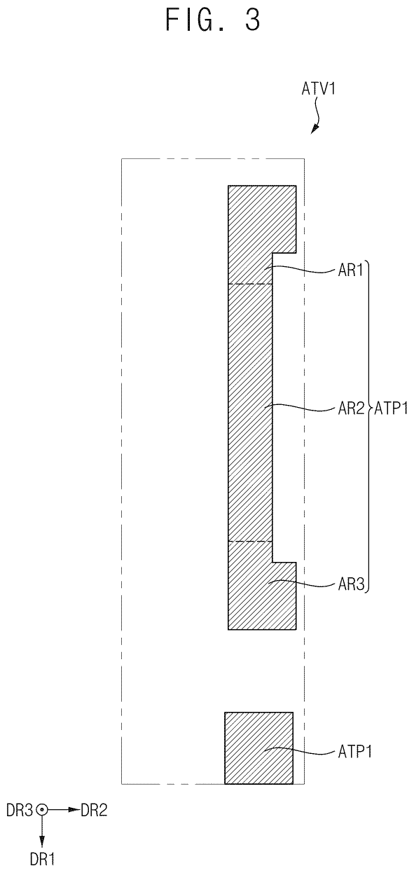

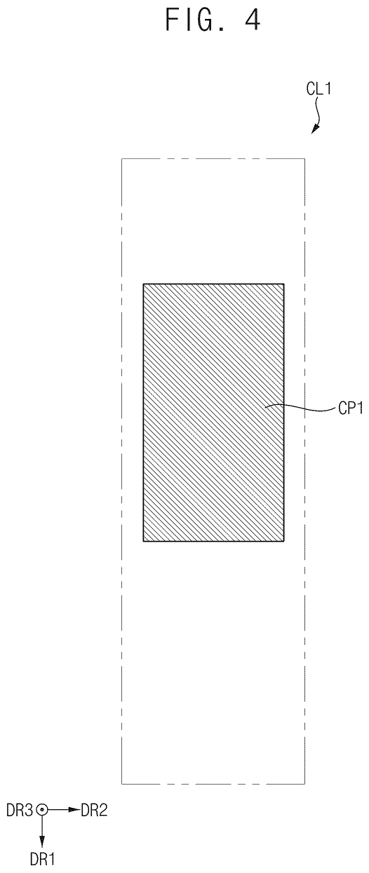

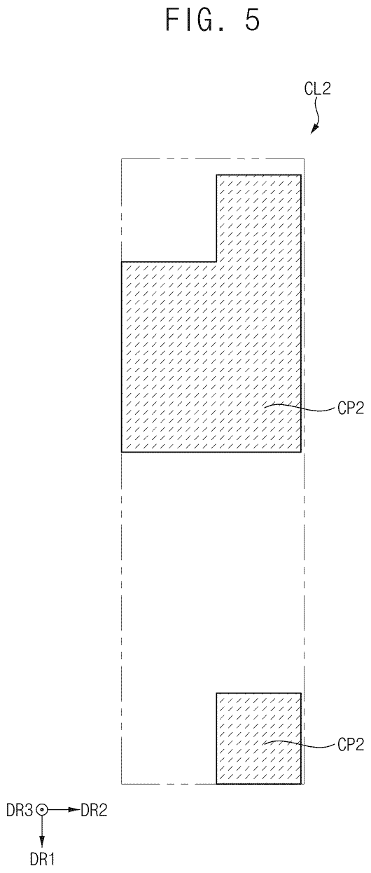

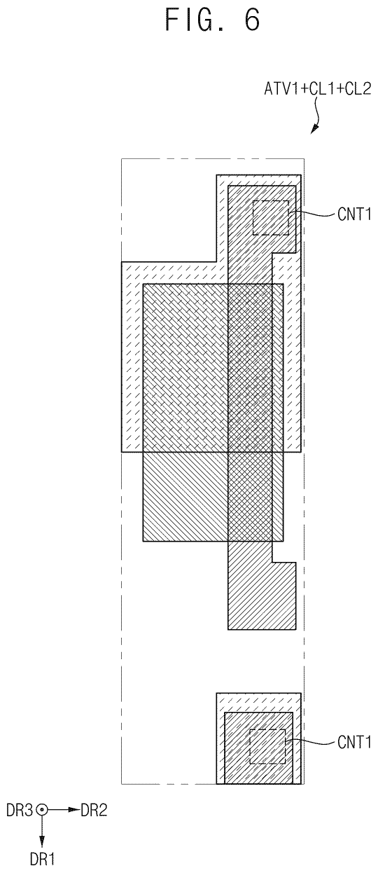

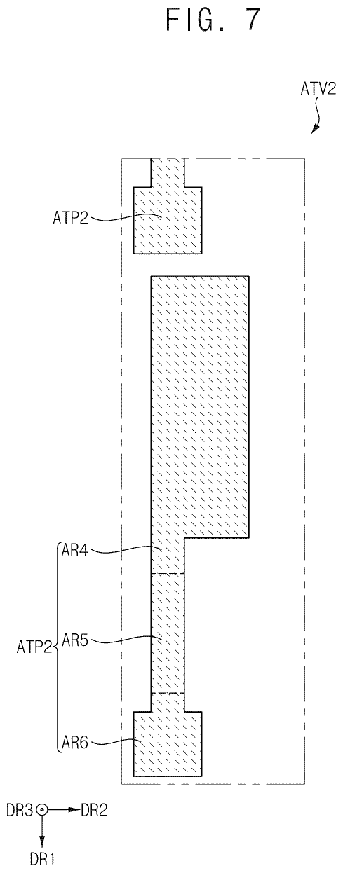

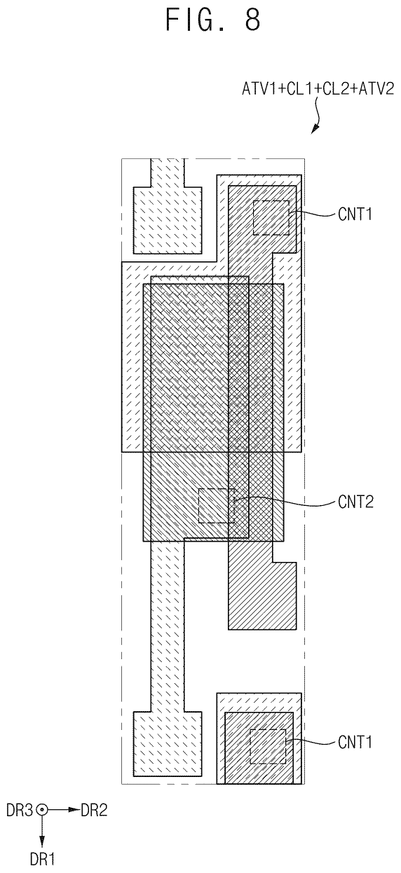

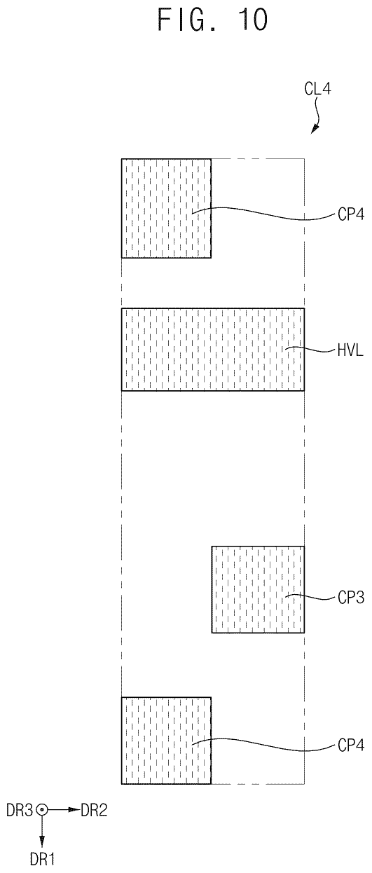

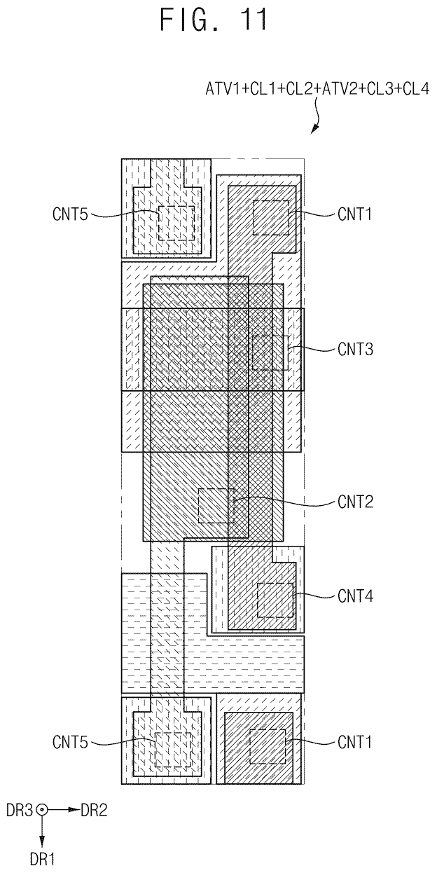

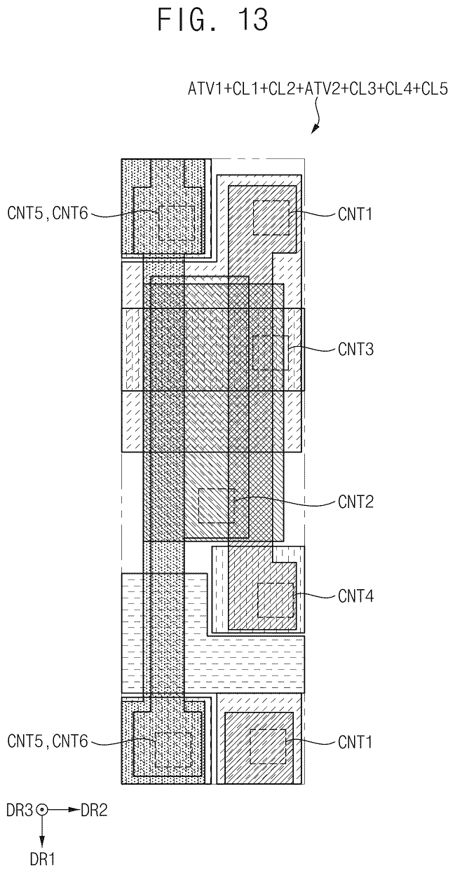

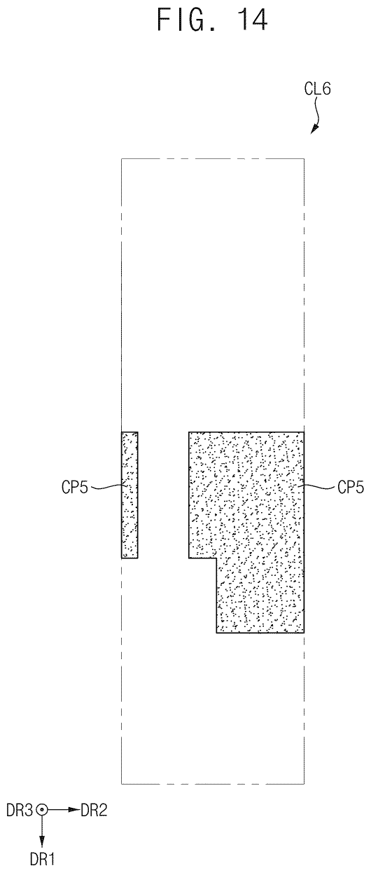

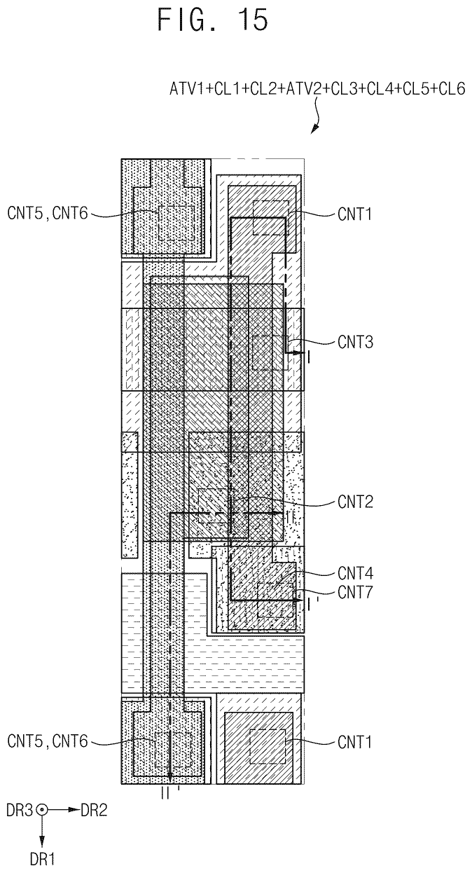

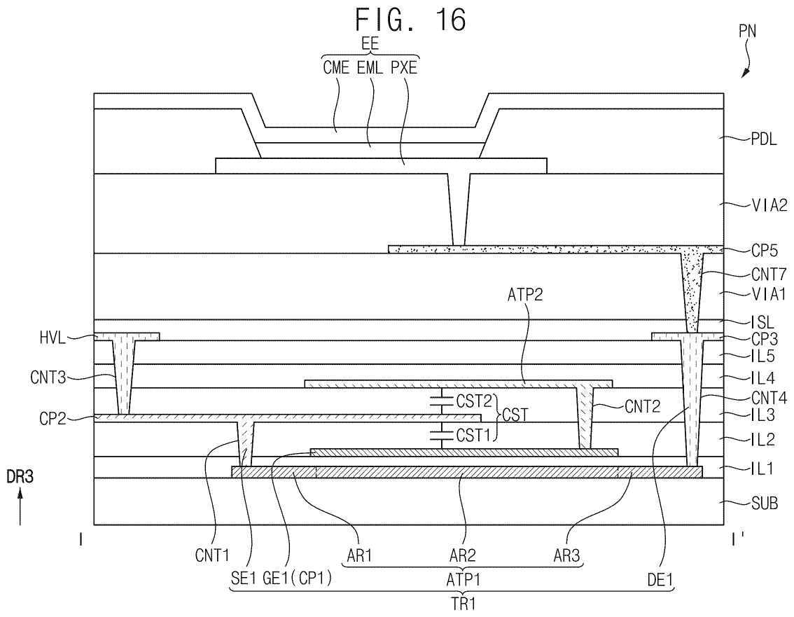

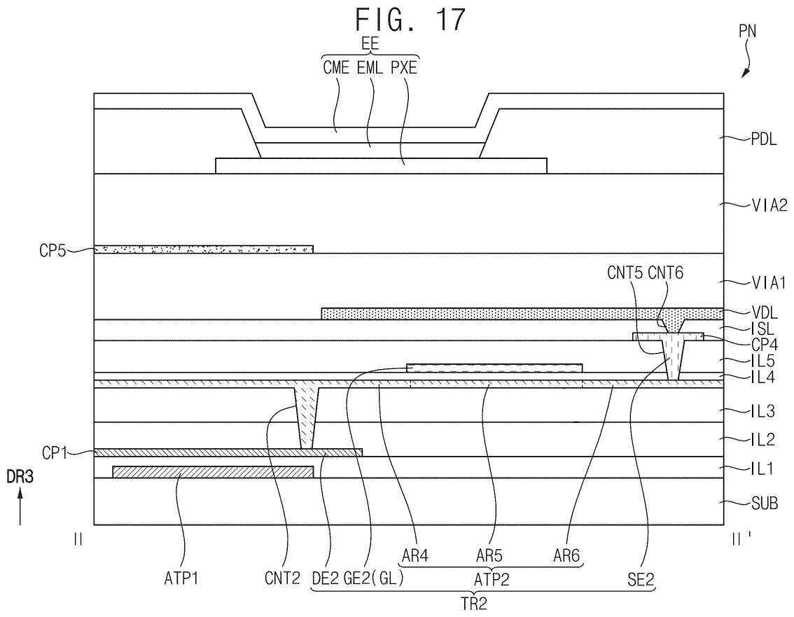

FIGS. 3, 4, 5, 6, 7, 8, 9, 10, 11, 12, 13, 14, and 15 are plan views illustrating an example of the pixel included in the display device of FIG. 1. FIG. 16 is a cross-sectional view illustrating a cross-section of the pixel of the display device of FIG. 1 taken along line I-I′ of FIG. 15. FIG. 17 is a cross-sectional view illustrating a cross-section of the pixel of the display device of FIG. 1 taken along line II-II′ of FIG. 15. As used herein, the “plan view” is a view in a thickness direction (i.e., third direction DR3) of the substrate SUB (See FIG. 16).

For example, FIGS. 3, 4, 5, 6,7, 8, 9, 10, 11, 12, 13, 14, and 15 are plan views illustrating one pixel PX among the plurality of pixels PX included in the display device DD of FIG. 1. A portion of the plurality of pixels PX may emit light of different colors. For example, the plurality of pixels PX may include a first pixel emitting red light, a second pixel emitting green light, and a third pixel emitting blue light. The first pixel, the second pixel, and the third pixel, which are adjacent to each other along the second direction DR2, may constitute one unit pixel. FIGS. 3, 4, 5, 6, 7, 8, 9, 10, 11, 12, 13, 14, and 15 are plan views illustrating one pixel among the first pixel, the second pixel, and the third pixel. However, the pixel PX and the unit pixel of the present disclosure may not be limited thereto, and the unit pixel may include four or more pixels PX, and the lights emitted by the pixels PX may also include various colors other than red, green, and blue.

Referring to FIGS. 2, 3, 4, 5, 6, 7, 8, 9, 10, 11, 12, 13, 14, 15, 16, and 17, the display device (e.g., the display device DD of FIG. 1) may include a substrate SUB, a first active layer ATV1, a first insulating layer IL1, a first conductive layer CL1, a second insulating layer IL2, a second conductive layer CL2, a third insulating layer IL3, a second active layer ATV2, a fourth insulating layer IL4, a third conductive layer CL3, a fifth insulating layer IL5, a fourth conductive layer CL4, an interlayer-insulating layer ISL, a fifth conductive layer CL5, a first via-insulating layer VIA1, a sixth conductive layer CL6, a second via-insulating layer VIA2, a pixel defining layer PDL, a pixel electrode PXE, an light-emitting layer EML, and a common electrode CME.

A first active pattern ATP1, a first gate electrode GE1, a first source electrode SE1, and a first drain electrode DE1 may define the first transistor TR1. A second active pattern ATP2, a second gate electrode GE2, a second source electrode SE2, and a second drain electrode DE2 may define the second transistor TR2. The pixel electrode PXE, the light-emitting layer EML, and the common electrode CME may define the light-emitting element EE.

The substrate SUB may include a transparent material or an opaque material. The substrate SUB may be made of a transparent resin substrate. Examples of the transparent resin substrate include a polyimide substrate, and the like. In this case, the polyimide substrate SUB may include a first organic layer, a first barrier layer, a second organic layer, and the like. Alternatively, the substrate SUB may include a quartz substrate, a synthetic quartz substrate, a calcium fluoride substrate, a non-alkali glass substrate, and the like. These may be used alone or in combination with each other.

The first active layer ATV1, the first conductive layer CL1, the second conductive layer CL2, the second active layer ATV2, the third conductive layer CL3, the fourth conductive layer CL4, the fifth conductive layer CL5, and the sixth conductive layer CL6 may be sequentially stacked on the substrate SUB.

The first active layer ATV1 may be disposed on the substrate SUB. In an embodiment, the first active layer ATV1 may include polycrystalline silicon. However, the material included in the first active layer ATV1 according to the embodiments of the present disclosure may not be limited thereto, and the first active layer ATV1 may include a metal oxide semiconductor, amorphous silicon, and the like.

The first active layer ATV1 may include a first active pattern ATP1. One pixel PX may include one first active pattern ATP1. The first active pattern ATP1 may extend in the first direction DR1. The first active pattern ATP1 may be arranged along the first direction DR1 and the second direction DR2. For example, the first active pattern ATP1 included in one pixel PX and the first active pattern ATP1 included in another pixel adjacent to the pixel PX may be spaced apart in the first direction DR1 or the second direction DR2.

The first active pattern ATP1 may include a first active area AR1, a second active area AR2, and a third active area AR3. The first active area AR1 and the second active area AR2 may be adjacent to each other in the first direction DR1. The second active area AR2 and the third active area AR3 may be adjacent to each other in the first direction DR1. The second active area AR2 may be located between the first active area AR1 and the third active area AR3.

The first conductive layer CL1 may be disposed on the first active pattern ATP1. Specifically, the first insulating layer IL1 may be disposed on the first active pattern ATP1, and the first conductive layer CL1 may be disposed on the first insulating layer IL1.

In an embodiment, the first insulating layer IL1 may include an inorganic insulating material. The above-mentioned inorganic insulating material may include silicon nitride (SiNx), silicon oxide (SiOx), silicon oxynitride (SiOxNy), and the like. These may be used alone or in combination. In an embodiment, the first insulating layer IL1 may cover the first active layer ATV1. For example, the first insulating layer IL1 may have a substantially uniform thickness and cover the first active layer ATV1. However, the first insulating layer IL1 according to embodiments of the present disclosure may not be limited thereto, and the first insulating layer IL1 may have a substantially flat upper surface and cover the first active layer ATV1.

In an embodiment, the first conductive layer CL1 may include a conductive material. For example, the conductive material may include silver (Ag), molybdenum (Mo), aluminum (Al), aluminum nitride (AlₓN_{y}), tungsten (W), tungsten nitride (WₓN_{y}), copper (Cu), indium tin oxide (“ITO”), indium zinc oxide (“IZO”), and the like. These may be used alone or in combination.

The first conductive layer CL1 may include a first conductive pattern CP1. In an embodiment, the first conductive pattern CP1 may overlap the first active pattern ATP1 in a plan view. For example, the first conductive pattern CP1 may overlap a portion of the first active pattern ATP1 in a plan view. Specifically, the first conductive pattern CP1 may overlap the second active area AR2 of the first active pattern ATP1 in a plan view. A portion where the first conductive pattern CP1 overlaps the first active pattern ATP1 in a plan view may be the first gate electrode GE1 of the first transistor TR1. In addition, a portion where the first active pattern ATP1 overlaps the first conductive pattern CP1 in a plan view may be the channel area of the first transistor TR1. In other words, the second active area AR2 may be a channel area of the first transistor TR1.

The second conductive layer CL2 may be disposed on the first conductive layer CL1. Specifically, the second insulating layer IL2 may be disposed on the first conductive layer CL1, and the second conductive layer CL2 may be disposed on the second insulating layer IL2.

In an embodiment, the second insulating layer IL2 may include an inorganic insulating material. In an embodiment, the second insulating layer IL2 may cover the first conductive layer CL1. For example, the second insulating layer IL2 may have a substantially uniform thickness and cover the first conductive layer CL1. However, the second insulating layer IL2 according to embodiments of the present disclosure may not be limited thereto, and the second insulating layer IL2 may have a substantially flat upper surface and cover the first conductive layer CL1.

In an embodiment, the second conductive layer CL2 may include a conductive material. The second conductive layer CL2 may include a second conductive pattern CP2. The second conductive pattern CP2 may extend in the second direction DR2. The second conductive pattern CP2 may be arranged along the first direction DR1. In an embodiment, the second conductive pattern CP2 may overlap the first active pattern ATP1 in a plan view. For example, the second conductive pattern CP2 may overlap each of the first active area AR1 and the second active area AR2 in a plan view.

A first contact hole CNT1 may be defined between the second conductive pattern CP2 and the first active pattern ATP1 to electrically connect the second conductive pattern CP2 and the first active pattern ATP1 to each other. For example, the first contact hole CNT1 may penetrate the first insulating layer IL1 and the second insulating layer IL2 in a thickness direction (e.g., the third direction DR3). Accordingly, a portion of the second conductive pattern CP2 may contact the first active area AR1 of the first active pattern ATP1 through the first contact hole CNT1. In an embodiment, the second conductive pattern CP2 may be the first source electrode SE1, which is a source electrode of the first transistor TR1. However, the present disclosure may not be limited thereto, and the second conductive pattern CP2 may also be a drain electrode of the first transistor TR1.

The second conductive pattern CP2 may overlap the first conductive pattern CP1 in a plan view. The storage capacitor CST may include a first storage capacitor CST1 and a second storage capacitor CST2. The second conductive pattern CP2 and the first conductive pattern CP1 may overlap each other in a plan view to define the first storage capacitor CST1. Specifically, the portion where the first conductive pattern CP1 overlaps the second conductive pattern CP2 in a plan view may be defined as the first terminal of the first storage capacitor CST1, and the portion where the second conductive pattern CP2 overlaps the first conductive pattern CP1 in a plan view may be defined as the second terminal of the first storage capacitor CST1.

The second active layer ATV2 may be disposed on the second conductive layer CL2. Specifically, the third insulating layer IL3 may be disposed on the second conductive layer CL2, and the second active layer ATV2 may be disposed on the third insulating layer IL3.

In an embodiment, the third insulating layer IL3 may include an inorganic insulating material. In an embodiment, the third insulating layer IL3 may cover the second conductive layer CL2. For example, the third insulating layer IL3 may have a substantially uniform thickness and cover the second conductive layer CL2. However, the third insulating layer IL3 according to embodiments of the present disclosure may not be limited thereto, and the third insulating layer IL3 may have a substantially flat upper surface and cover the second conductive layer CL2.

In an embodiment, the second active layer ATV2 may include polysilicon. In addition, in an embodiment, the second active layer ATV2 may include substantially the same material as the first active layer ATV1. For example, the first active layer ATV1 may include polysilicon, and the second active layer ATV2 may include polysilicon. However, the material included in the second active layer ATV2 according to embodiments of the present disclosure may not be limited thereto, and the second active layer ATV2 may include a metal oxide semiconductor, amorphous silicon, and the like.

The second active layer ATV2 may include a second active pattern ATP2. The second active pattern ATP2 may extend in the first direction DR1. The second active pattern ATP2 may be arranged along the first direction DR1 and the second direction DR2. For example, the second active pattern ATP2 included in one pixel PX and the second active pattern ATP2 included in another pixel adjacent to the pixel PX may be spaced apart from each other in the first direction DR1 or the second direction DR2.

The second active pattern ATP2 may include a fourth active area AR4, a fifth active area AR5, and a sixth active area AR6. The fourth active area AR4 and the fifth active area AR5 may be adjacent to each other in the first direction DR1. The fifth active area AR5 and the sixth active area AR6 may be adjacent to each other in the first direction DR1. The fifth active area AR5 may be located between the fourth active area AR4 and the sixth active area AR6.

The second active pattern ATP2 may overlap the first conductive pattern CP1 in a plan view. A second contact hole CNT2 which electrically connects the second active pattern ATP2 and the first conductive pattern CP1 to each other may be defined between the second active pattern ATP2 and the first conductive pattern CP1.

For example, the second contact hole CNT2 may penetrate the second insulating layer IL2 and the third insulating layer IL3 in a thickness direction. Accordingly, the fourth active area AR4 of the second active pattern ATP2 may contact a portion of the first conductive pattern CP1 through the second contact hole CNT2. In an embodiment, a portion where the first conductive pattern CP1 contacts the fourth active area AR4 may be the second drain electrode DE2, which is a drain electrode of the second transistor TR2. However, the present disclosure may not be limited thereto, and a portion where the first conductive pattern CP1 contacts the fourth active area AR4 may be a source electrode of the second transistor TR2.

The second active pattern ATP2 may overlap the second conductive pattern CP2 in a plan view. For example, the fourth active area AR4 of the second active pattern ATP2 may overlap the second conductive pattern CP2 in a plan view. The second active pattern ATP2 and the second conductive pattern CP2 may overlap each other in a plan view to define a second storage capacitor CST2. Specifically, a portion where the second conductive pattern CP2 overlaps the second active pattern ATP2 in a plan view may be defined as a first terminal of the second storage capacitor CST2, and a portion where the second active pattern ATP2 overlaps the second conductive pattern CP2 in a plan view may be defined as a second terminal of the second storage capacitor CST2. The first conductive pattern CP1, the second conductive pattern CP2, and the second active pattern ATP2 may together define the storage capacitor CST. In other words, the storage capacitor CST may have a dual capacitor structure in which two capacitors overlap in a plan view. Accordingly, the storage capacity of the storage capacitor CST may be improved.

In an embodiment, the second active pattern ATP2 may overlap a portion of the first active pattern ATP1 in a plan view. Accordingly, an area of the pixel PX including the first transistor TR1 and the second transistor TR2 may be reduced.

The third conductive layer CL3 may be disposed on the second active layer ATV2. The fourth conductive layer CL4 may be disposed on the third conductive layer CL3. Specifically, the fourth insulating layer IL4 may be disposed on the second active layer ATV2, and the third conductive layer CL3 may be disposed on the fourth insulating layer IL4. In addition, the fifth insulating layer IL5 may be disposed on the third conductive layer CL3, and the fourth conductive layer CL4 may be disposed on the fifth insulating layer IL5.

In an embodiment, the fourth insulating layer IL4 and the fifth insulating layer IL5 may include an inorganic insulating material. In an embodiment, the fourth insulating layer IL4 may cover the second active layer ATV2. For example, the fourth insulating layer IL4 may have a substantially uniform thickness and cover the second active layer ATV2. However, the fourth insulating layer IL4 according to embodiments of the present disclosure may not be limited thereto, and the fourth insulating layer IL4 may have a substantially flat upper surface and cover the second active layer ATV2.

In an embodiment, the fifth insulating layer IL5 may cover the third conductive layer CL3. For example, the fifth insulating layer IL5 may have a substantially uniform thickness and cover the third conductive layer CL3. However, the fifth insulating layer IL5 according to embodiments of the present disclosure may not be limited thereto, and the fifth insulating layer IL5 may have a substantially flat upper surface and cover the third conductive layer CL3.

In an embodiment, each of the third conductive layer CL3 and the fourth conductive layer CL4 may include a conductive material. The third conductive layer CL3 may include a gate voltage line GL. The gate write signal GW may be applied to the gate voltage line GL. The gate voltage line GL may extend in the second direction DR2. In addition, the gate voltage line GL may be arranged along the first direction DR1. The gate voltage line GL may overlap the fifth active area AR5 of the second active pattern ATP2 in a plan view. A portion where the gate voltage line GL overlaps the fifth active area AR5 in a plan view may be the second gate electrode GE2, which is a gate electrode of the second transistor TR2. In addition, the portion where the fifth active area AR5 overlaps the gate voltage line GL in a plan view may be a channel area of the second transistor TR2.

The fourth conductive layer CL4 may include a third conductive pattern CP3, a fourth conductive pattern CP4, and a horizontal power voltage line HVL. The third conductive pattern CP3, the fourth conductive pattern CP4, and the horizontal power voltage line HVL may be spaced apart from each other in a plan view. For example, in one pixel PX, the third conductive pattern CP3 may be spaced apart from the horizontal power voltage line HVL in a first direction DR1. In the one pixel PX, the fourth conductive pattern CP4 may be spaced apart from the horizontal power voltage line HVL in a first direction DR1. A first power voltage (e.g., the first power voltage ELVDD of FIG. 2) may be applied to the horizontal power voltage line HVL.

The horizontal power voltage line HVL may extend in the second direction DR2. A horizontal power voltage line HVL may be arranged along a first direction DR1. The horizontal power voltage line HVL may overlap a second conductive pattern CP2 in a plan view. A third contact hole CNT3 may be defined between the horizontal power voltage line HVL and the second conductive pattern CP2 to electrically connect the horizontal power voltage line HVL and the second conductive pattern CP2. Specifically, the third contact hole CNT3 may penetrate the third insulating layer IL3, the fourth insulating layer IL4, and the fifth insulating layer IL5 in a thickness direction. Accordingly, the horizontal power voltage line HVL may contact the second conductive pattern CP2 through the third contact hole CNT3. Accordingly, the first power voltage ELVDD may be transmitted to the first active area AR1 along the horizontal power voltage line HVL and the second conductive pattern CP2.

The third conductive pattern CP3 may overlap the third active area AR3 of the first active pattern ATP1 in a plan view. A fourth contact hole CNT4 may be defined between the third conductive pattern CP3 and the first active pattern ATP1 to electrically connect the third conductive pattern CP3 and the first active pattern ATP1. Specifically, the fourth contact hole CNT4 may penetrate the first insulating layer IL1, the second insulating layer IL2, the third insulating layer IL3, the fourth insulating layer IL4, and the fifth insulating layer IL5 in a thickness direction. Accordingly, the third conductive pattern CP3 may contact the third active area AR3 of the first active pattern ATP1 through the fourth contact hole CNT4. The third conductive pattern CP3 may be a first drain electrode DE1, which is a drain electrode of the first transistor TR1. However, the present disclosure may not be limited thereto, and the third conductive pattern CP3 may be a source electrode of the first transistor TR1.

In an embodiment, the third conductive pattern CP3 and the gate voltage line GL may contact each other in a plan view. In another embodiment, the third conductive pattern CP3 and the gate voltage line GL may overlap each other in a plan view. In still another embodiment, the third conductive pattern CP3 and the gate voltage line GL may be spaced apart from each other in a plan view.

The fourth conductive pattern CP4 may overlap the sixth active area AR6 of the second active pattern ATP2 in a plan view. A fifth contact hole CNT5 may be defined between the fourth conductive pattern CP4 and the second active pattern ATP2 to electrically connect the fourth conductive pattern CP4 and the second active pattern ATP2. Specifically, the fifth contact hole CNT5 may penetrate the fourth insulating layer IL4 and the fifth insulating layer IL5 in a thickness direction. Accordingly, the fourth conductive pattern CP4 may contact the sixth active area AR6 of the second active pattern ATP2 through the fifth contact hole CNT5. The fourth conductive pattern CP4 may be the second source electrode SE2, which is a source electrode of the second transistor TR2. However, the present disclosure may not be limited thereto, and the fourth conductive pattern CP4 may also be a drain electrode of the second transistor TR2.

In an embodiment, the fourth conductive pattern CP4 and the gate voltage line GL may contact each other in a plan view. In another embodiment, the fourth conductive pattern CP4 and the gate voltage line GL may overlap each other in a plan view. In still another embodiment, the fourth conductive pattern CP4 and the gate voltage line GL may be spaced apart from each other in a plan view.

In an embodiment, the fourth conductive pattern CP4 and the second conductive pattern CP2 may adjoin each other in a plan view. In another embodiment, the fourth conductive pattern CP4 and the second conductive pattern CP2 may overlap each other in a plan view. In still another embodiment, the fourth conductive pattern CP4 and the second conductive pattern CP2 may be spaced apart from each other in a plan view.

The fifth conductive layer CL5 may be disposed on the fourth conductive layer CL4. Specifically, the interlayer-insulating layer ISL may be disposed on the fourth conductive layer CL4, and the fifth conductive layer CL5 may be disposed on the interlayer-insulating layer ISL.

In an embodiment, the interlayer-insulating layer ISL may include an inorganic insulating material. In an embodiment, the interlayer-insulating layer ISL may cover the fourth conductive layer CL4. For example, the interlayer-insulating layer ISL may have a substantially uniform thickness and cover the fourth conductive layer CL4. However, the interlayer-insulating layer ISL according to embodiments of the present disclosure may not be limited thereto, and the interlayer-insulating layer ISL may have a substantially flat upper surface and cover the fourth conductive layer CL4.

In an embodiment, the fifth conductive layer CL5 may include a conductive material. The data voltage line VDL may extend along the first direction DR1. The data voltage line VDL may be arranged along the second direction DR2. A data voltage (e.g., the data voltage VD of FIG. 2) may be applied to the data voltage line VDL. A sixth contact hole CNT6 may be defined between the data voltage line VDL and the fourth conductive pattern CP4 to electrically connect the data voltage line VDL and the fourth conductive pattern CP4. Specifically, the sixth contact hole CNT6 may penetrate the interlayer-insulating layer ISL in a thickness direction. Accordingly, the data voltage line VDL may contact the fourth conductive pattern CP4 through the sixth contact hole CNT6.

In an embodiment, the fifth contact hole CNT5 and the sixth contact hole CNT6 may overlap each other in a plan view. The data voltage line VDL may be electrically connected to the sixth active area AR6 of the second active pattern ATP2 through the fifth contact hole CNT5 and the sixth contact hole CNT6.

The sixth conductive layer CL6 may be disposed on the fifth conductive layer CL5. Specifically, the first via-insulating layer VIA1 may be disposed on the fifth conductive layer CL5, and the sixth conductive layer CL6 may be disposed on the first via-insulating layer VIA1.

In an embodiment, the first via-insulating layer VIA1 may include an organic insulating material, such as a polyimide (“PI”). In an embodiment, the first via-insulating layer VIA1 may have a substantially flat upper surface and may cover the fifth conductive layer CL5.

In an embodiment, the sixth conductive layer CL6 may include a conductive material. The sixth conductive layer CL6 may include a fifth conductive pattern CP5. In an embodiment, the fifth conductive pattern CP5 may be spaced apart from the horizontal power voltage line HVL in the first direction DR1 on the plane. In an embodiment, the fifth conductive pattern CP5 may contact the data voltage line VDL in a plan view. In another embodiment, the fifth conductive pattern CP5 may overlap the data voltage line VDL in a plan view. In still another embodiment, the fifth conductive pattern CP5 may be spaced apart from the data voltage line VDL in a plan view.

In an embodiment, the fifth conductive pattern CP5 may overlap the third conductive pattern CP3 in a plan view. A seventh contact hole CNT7 may be defined between the fifth conductive pattern CP5 and the third conductive pattern CP3 to electrically connect the fifth conductive pattern CP5 and the third conductive pattern CP3 to each other. Specifically, the seventh contact hole CNT7 may penetrate the interlayer-insulating layer ISL and the first via-insulating layer VIA1 in a thickness direction. Accordingly, the fifth conductive pattern CP5 may contact the third conductive pattern CP3 through the seventh contact hole CNT7.

In an embodiment, the seventh contact hole CNT7 may overlap the fourth contact hole CNT4 in a plan view. In an embodiment, the first contact hole CNT1, the third contact hole CNT3, the fourth contact hole CNT4, and the seventh contact hole CNT7 may be arranged along the first direction DR1.

In an embodiment, a resolution of the display device may be about 1500 pixel per inch (ppi) to about 2000 ppi. Preferably, the resolution of the display device may be about 1750 ppi to about 2000 ppi. For example, a length of one pixel PX in the first direction DR1 may be about 12.7 micrometers (μm) to about 16.93 μm. Preferably, the length of the one pixel PX in the first direction DR1 may be about 14.56 μm to about 16.93 μm. In addition, a length of the one pixel PX in the second direction DR2 may be about 4.23 μm to about 5.64 μm. Preferably, the length of the one pixel PX in the second direction DR2 may be about 4.85 μm to about 5.64 μm.

The second via-insulating layer VIA2 may be disposed on the sixth conductive layer CL6. In an embodiment, the second via-insulating layer VIA2 may include an organic insulating material such as polyimide. A upper surface of the second via-insulating layer VIA2 may have a substantially flat surface and may cover the sixth conductive layer CL6.

The pixel electrode PXE may be disposed on the second via-insulating layer VIA2. The pixel electrode PXE may be electrically connected to the sixth conductive layer CL6 through a contact hole penetrating the second via-insulating layer VIA2 in a thickness direction. Specifically, the pixel electrode PXE may contact the fifth conductive pattern CP5 through the contact hole.

In an embodiment, the pixel electrode PXE may include a metal, an alloy, a metal nitride, a conductive metal oxide, a transparent conductive material, and the like. These may be used alone or in combination with each other.

The pixel defining layer PDL may be disposed on a pixel electrode PXE. The pixel defining layer PDL may partially cover the pixel electrode PXE. In addition, a contact hole exposing at least a portion of the pixel electrode PXE may be defined in the pixel defining layer PDL. For example, the contact hole of the pixel defining layer PDL may expose a central portion of the pixel electrode PXE, and the pixel defining layer PDL may cover an edge of the pixel electrode PXE. The pixel defining layer PDL may include an organic insulating material, such as a polyimide.

The light-emitting layer EML may be disposed on the pixel electrode PXE. The light-emitting layer EML may be disposed on the pixel electrode PXE exposed by the contact hole of the pixel defining layer PDL. The light-emitting layer EML may include an organic light-emitting material, a quantum dot, and the like.

The common electrode CME may be disposed on the light-emitting layer EML and the pixel defining layer PDL. The common electrode CME may include aluminum, platinum (Pt), silver, magnesium (Mg), gold (Au), chromium (Cr), tungsten, titanium (Ti), and the like. These may be used alone or in combination with each other.

As described above, the display device may include the first active pattern ATP1 disposed on the substrate SUB and extending along the first direction DR1, the first conductive pattern CP1 disposed on the first active pattern ATP1 and overlapping a portion of the first active pattern ATP1 in a plan view, the second conductive pattern CP2 disposed on the first conductive pattern CP1 and extending in the second direction DR2, and the second active pattern ATP2 disposed on the second conductive pattern CP2 and defining the storage capacitor CST together with the first conductive pattern CP1 and the second conductive pattern CP2. In addition, since the display device includes the sensing circuit for external compensation (e.g., the sensing circuit SSC of FIG. 1), one pixel PX included in the display device may include two transistors. Accordingly, the number of pixels PX included in the display device increases, so that the display device may be implemented with a high resolution.

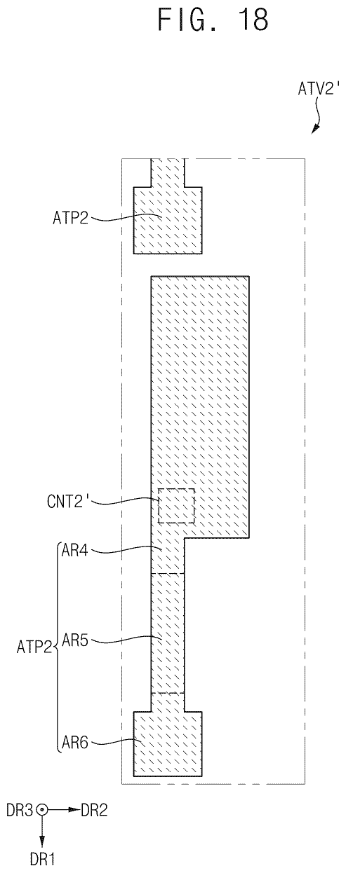

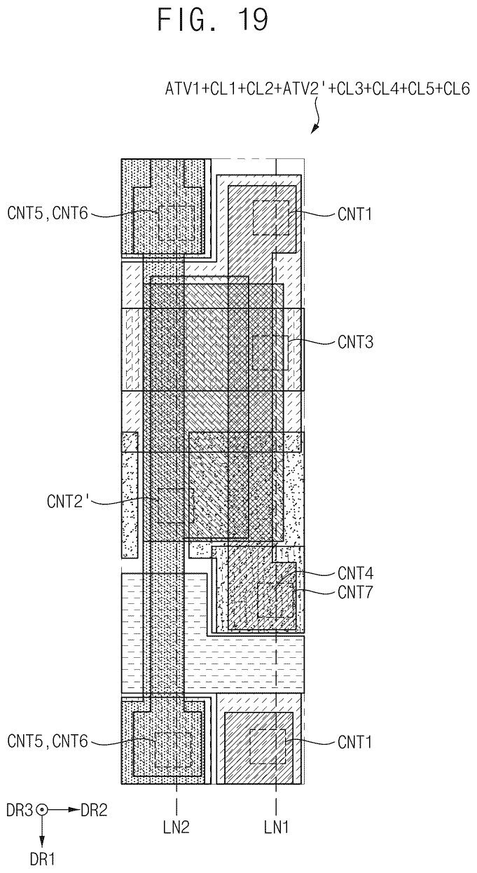

FIGS. 18 and 19 are plan views illustrating another example of the pixel included in the display device of FIG. 1.

The display device described with reference to FIGS. 18 and 19 is substantially a same as the display device described with reference to FIGS. 3, 4, 5, 6, 7, 8, 9, 10, 11, 12, 13, 14, 15, 16, and 17 except for a position of a second contact hole CNT2′, in a plan view.

Hereinafter, contents that overlap with the contents described with reference to FIGS. 3, 4, 5, 6, 7, 8, 9, 10, 11, 12, 13, 14, 15, 16, and 17 may be omitted or simplified.

Referring to FIGS. 18 and 19, the first contact hole CNT1, the third contact hole CNT3, and the fourth contact hole CNT4 may be arranged along a first imaginary vertical line LN1 in a plan view. The first imaginary vertical line LN1 may be a straight line parallel to the first direction DR1. In other words, the first contact hole CNT1, the third contact hole CNT3, and the fourth contact hole CNT4 may be arranged in a line along the first direction DR1. In addition, since the seventh contact hole CNT7 overlaps the fourth contact hole CNT4 in a plan view, the seventh contact hole CNT7 may also be arranged along the first imaginary vertical line LN1.

In an embodiment, the second contact hole CNT2′ and the fifth contact hole CNT5 may be arranged along a second imaginary vertical line LN2 in a plan view. The second imaginary vertical line LN2 may be a straight line parallel to the first direction DR1. In addition, the second imaginary vertical line LN2 may be spaced apart from the first imaginary vertical line LN1 in a direction opposite to the second direction DR2. In other words, the second contact hole CNT2′ and the fifth contact hole CNT5 may be arranged in a line along the first direction DR1. In addition, since the sixth contact hole CNT6 overlaps the fifth contact hole CNT5 in a plan view, the sixth contact hole CNT6 may also be arranged along the second imaginary vertical line LN2 in a plan view.

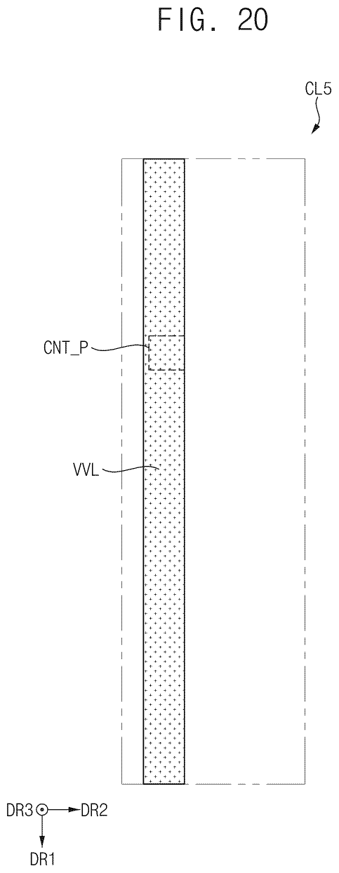

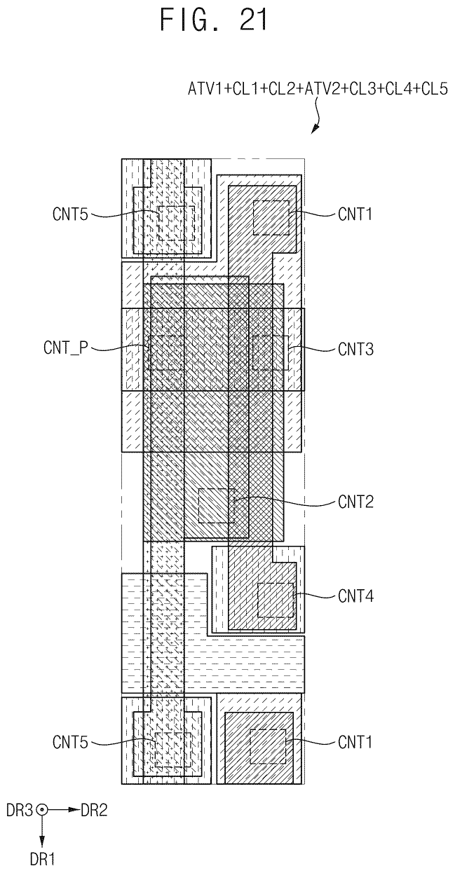

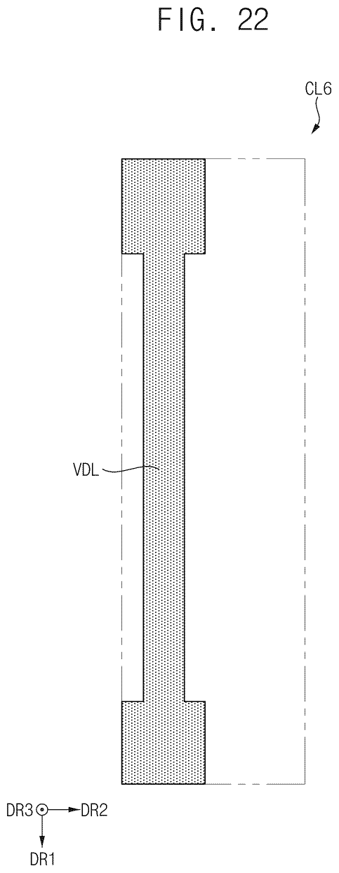

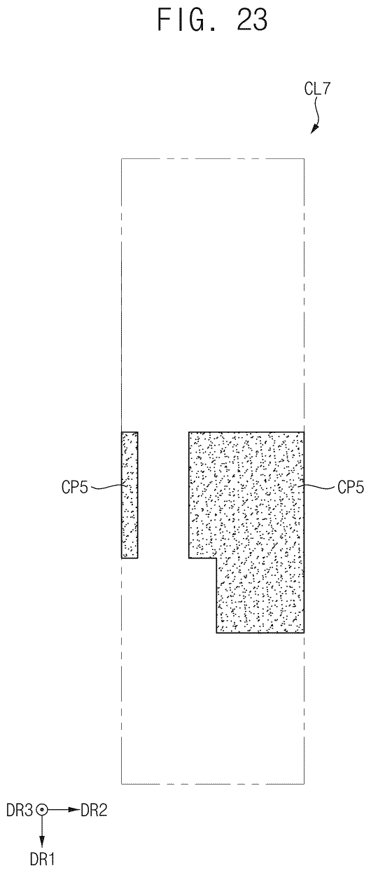

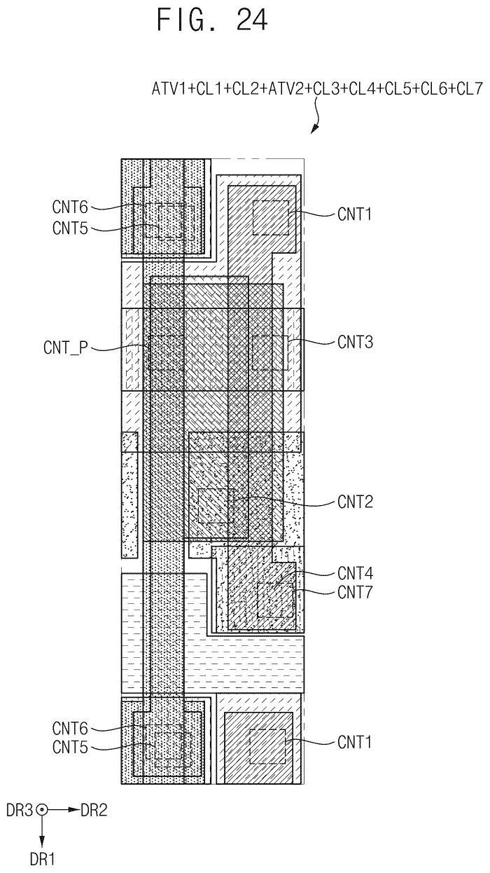

FIGS. 20, 21, 22, 23, and 24 are plan views illustrating still another example of the pixel included in the display device of FIG. 1.

The display device described with reference to FIGS. 20, 21, 22, 23, and 24 is substantially a same as the display device described with reference to FIGS. 3, 4, 5, 6, 7, 8, 9, 10, 11, 12, 13, 14, 15, 16, and 17 except for a vertical power voltage line VVL.

Hereinafter, contents overlapping with contents described with reference to FIGS. 3, 4, 5, 6, 7, 8, 9, 10, 11, 12, 13, 14, 15, 16, and 17 may be omitted or simplified.

Referring to FIGS. 20 to 24, the display device may include a fifth conductive layer CL5 including a vertical power voltage line VVL. The fifth conductive layer CL5 may include a vertical power voltage line VVL. A sixth conductive layer CL6 and a seventh conductive layer CL7 may include a data voltage line VDL and a fifth conductive pattern CP5, respectively.

The first power voltage may be applied to the vertical power voltage line VVL. The vertical power voltage line VVL may extend in the first direction DR1. In addition, the vertical power voltage line VVL may be arranged in the second direction DR2. The vertical power voltage line VVL may overlap the horizontal power voltage line HVL in a plan view. In addition, the vertical power voltage line VVL may overlap the data voltage line VDL in a plan view.

The sixth conductive layer CL6 and the seventh conductive layer CL7 may be sequentially disposed on the fifth conductive layer CL5. The fifth conductive layer CL5 may be disposed on the fourth conductive layer CL4. For example, the vertical power voltage line VVL may be disposed on the horizontal power voltage line HVL. In addition, the vertical power voltage line VVL may be disposed under the data voltage line VDL. That is, the vertical power voltage line VVL may be disposed between the horizontal power voltage line HVL and the data voltage line VDL in a cross-sectional view.

Between the vertical power voltage line VVL and the horizontal power voltage line HVL, a power voltage contact hole CNT_P may be defined to electrically connect the vertical power voltage line VVL and the horizontal power voltage line HVL to each other. Specifically, the power voltage contact hole CNT_P may penetrate an insulating layer disposed between the fourth conductive layer CL4 and the fifth conductive layer CL5 in the thickness direction. Accordingly, the vertical power voltage line VVL may contact the horizontal power voltage line HVL through the power voltage contact hole CNT_P. Accordingly, the driving current generated by the first power voltage applied to the vertical power voltage line VVL and the horizontal power voltage line HVL may be transmitted to the first active area AR1. In other words, the first power voltage may be applied to the first power voltage line having a mesh structure formed by a vertical power voltage line VVL and a horizontal power voltage line HVL.

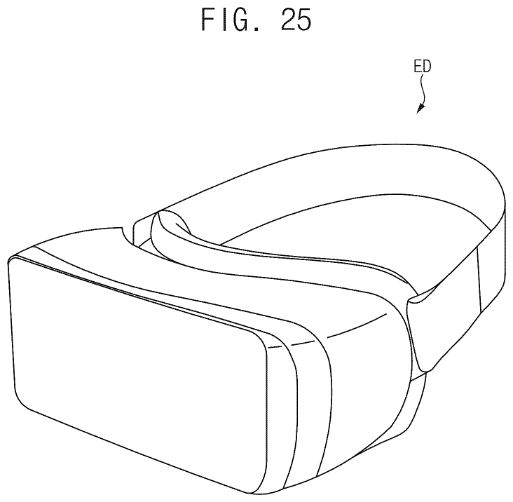

FIG. 25 is a view illustrating an electronic device implemented by the display device of FIG. 1.

Referring to FIG. 25, the display device DD of FIG. 1 may be applied to an electronic device ED for virtual reality (“VR”) including a head mounted display. A virtual reality image may be viewed through the display device DD included in the electronic device ED. However, the electronic device ED according to embodiments of the present invention is not limited thereto, and the electronic device ED may have various forms in addition to the head mounted type.

The device electronic device may include a processor, a memory device, a storage device, an input/output device, a power supply, and a display device. In such an embodiment, the display device may be the display device of FIG. 1. In addition, the electronic device ED may further include a plurality of ports for communicating with a video card, a sound card, a memory card, a universal serial bus (USB) device, other electronic devices, and the like.

The processor may perform various computing functions or various tasks. The processor may be a micro-processor, a central processing unit (CPU), an application processor (AP), and the like. The processor may be coupled to other components via an address bus, a control bus, a data bus, and the like. Further, the processor may be coupled to an extended bus such as a peripheral component interconnection (PCI) bus.

The memory device may store data for operations of the electronic device. In an embodiment, for example, the memory device may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device such as a dynamic random access memory (DRAM) device, a static random access memory (SRAM) device, a mobile DRAM device, or the like.

The storage device may include a solid-state drive (SSD) device, a hard disk drive (HDD) device, a CD-ROM device, or the like. The I/O device may include an input device such as a keyboard, a keypad, a mouse device, a touch-pad, a touch-screen, or the like and an output device such as a printer, a speaker, or the like. In some embodiments, the display device may be included in the I/O device. The power supply may provide power for operations of the electronic device. The display device may be coupled to other components via the buses or other communication links.

The devices according to the embodiments may be applied to a display device included in a computer, a notebook, a mobile phone, a smartphone, a smart pad, a PMP, a PDA, an MP3 player, and the like.

Although the methods and the systems according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a substrate;
a first active pattern disposed on the substrate, and extending in a first direction;
a first conductive pattern disposed on the first active pattern, and overlapping a portion of the first active pattern in a plan view;
a second conductive pattern disposed on the first conductive pattern, and extending in a second direction which intersects with the first direction; and
a second active pattern disposed on the second conductive layer, and defining a storage capacitor with the first conductive pattern and the second conductive pattern.

2. The display device of claim 1, wherein the storage capacitor includes:
a first storage capacitor defined by overlapping portions of the first conductive pattern and the second conductive pattern; and
a second storage capacitor defined by overlapping portions of the second conductive pattern and the second active pattern.

3. The display device of claim 1, further comprising:
a gate voltage line disposed on the second active pattern, extending in the second direction, and to which a gate voltage is configured to be applied;
a horizontal power voltage line disposed on the gate voltage line, and extending in the second direction;
a third conductive pattern disposed on the gate voltage line, and spaced apart from the horizontal power voltage line in the first direction; and
a fourth conductive pattern disposed on the gate voltage line, and spaced apart from the third conductive pattern and the horizontal power voltage line.

4. The display device of claim 3, wherein the second conductive pattern is electrically connected to the first active pattern, and
the third conductive pattern is spaced apart from the second conductive pattern in the first direction in a plan view, and is electrically connected to the first active pattern.

5. The display device of claim 4, wherein the first active pattern, the first conductive pattern, the second conductive pattern, and the third conductive pattern define a driving transistor together.

6. The display device of claim 5, wherein the second conductive pattern is a source electrode of the driving transistor,
the third conductive pattern is a drain electrode of the driving transistor, and
a portion of the first conductive pattern overlapping the first active pattern in the plan view is a gate electrode of the driving transistor.

7. The display device of claim 4, wherein the first conductive pattern is electrically connected to the second active pattern, and
the fourth conductive pattern is spaced apart from the first conductive pattern in the first direction in a plan view, and is electrically connected to the second active pattern.

8. The display device of claim 7, wherein the second active pattern, the gate voltage line, the first conductive pattern, and the fourth conductive pattern define a switching transistor together.

9. The display device of claim 8, wherein the first conductive pattern is a drain electrode of the switching transistor,
the fourth conductive pattern is a source electrode of the switching transistor, and
a portion of the gate voltage line overlapping the second active pattern in the plan view is a gate electrode of the switching transistor.

10. The display device of claim 7, wherein a power voltage is configured to be applied to the horizontal power voltage line, and
the horizontal power voltage line is electrically connected to the second conductive pattern.

11. The display device of claim 10, wherein the second conductive pattern and the first active pattern are connected through a first contact hole,
the second active pattern and the first conductive pattern are connected through a second contact hole,
the horizontal power voltage line and the second conductive pattern are connected through a third contact hole,
the third conductive pattern and the first active pattern are connected through a fourth contact hole, and
the fourth conductive pattern and the second active pattern are connected through a fifth contact hole.

12. The display device of claim 11, wherein the first contact hole, the third contact hole, and the fourth contact hole are arranged along a first imaginary vertical line parallel to the first direction, in a plan view, and
the second contact hole and the fifth contact hole are arranged along a second imaginary vertical line parallel to the first direction and spaced apart from the first imaginary vertical line, in a plan view.

13. The display device of claim 11, further comprising:
a data voltage line disposed on the horizontal power voltage line, and extending in the first direction; and
a fifth conductive pattern disposed on the data voltage line, and spaced apart from the horizontal power voltage line in the first direction, in a plan view.

14. The display device of claim 13, wherein the data voltage line is connected to the fourth conductive pattern through a sixth contact hole, and
the sixth contact hole overlaps the fifth contact hole in the plan view.

15. The display device of claim 13 wherein the fifth conductive pattern is electrically connected to the third conductive pattern through a seventh contact hole, and
the seventh contact hole overlaps the fourth contact hole in the plan view.

16. The display device of claim 13 wherein the fifth conductive pattern and the data voltage line adjoin each other in a plan view.

17. The display device of claim 13, further comprising:
a vertical power voltage line disposed between the horizontal power voltage line and the data voltage line, and extending in the first direction.

18. The display device of claim 1, wherein the second active pattern overlaps a portion of the first active pattern in the plan view.

19. A display device comprising:
a substrate;
a first active pattern disposed on the substrate, and extending in the first direction;
a first conductive pattern disposed on the first active pattern, and overlapping a portion of the first active pattern in a plan view;
a second conductive pattern disposed on the first conductive pattern, extending in a second direction which intersects with the first direction, and contacting a portion of the first active pattern through a first contact hole;
a second active pattern disposed on the second conductive pattern, overlapping a portion of each of the first conductive pattern and the second conductive pattern in the plan view, and contacting a portion of the first conductive pattern through a second contact hole;
a gate voltage line disposed on the second active pattern, extending in the second direction, and to which a gate voltage is configured to be applied;
a horizontal power voltage line disposed on the gate voltage line, to which a power voltage is configured to be applied, and contacting a portion of the second conductive pattern through a third contact hole;
a third conductive pattern disposed in a same layer as the horizontal power voltage line, and contacting a portion of the first active pattern through a fourth contact hole; and
a fourth conductive pattern disposed in a same layer as the horizontal power voltage line, and contacting a portion of the second active pattern through a fifth contact hole.

20. The display device of claim 19, wherein the first contact hole, the third contact hole, and the fourth contact hole are arranged along a first imaginary vertical line parallel to the first direction in a plan view, and
the second contact hole and the fifth contact hole are arranged along a second imaginary vertical line parallel to the first direction and spaced apart from the first imaginary vertical line.

21. An electronic device comprising:
a display device configured to display an image; and
a processor configured to drive the display device;
wherein the display device includes:
a substrate;
a first active pattern disposed on the substrate, and extending in a first direction;
a first conductive pattern disposed on the first active pattern, and overlapping a portion of the first active pattern in a plan view;
a second conductive pattern disposed on the first conductive pattern, and extending in a second direction which intersects with the first direction; and
a second active pattern disposed on the second conductive layer, and defining a storage capacitor with the first conductive pattern and the second conductive pattern.
